(19) United States
(12) Patent Application Publication
(10) Pub. No.: US 2014/0042008 A1
(43) Pub. Date: Feb. 13, 2014

(54) TOUCH PANEL

(71) Applicant: PANASONIC CORPORATION, Osaka (JP)

(72) Inventors: Tetsutaro NASU, Nara (JP); Keishiro MURATA, Kyoto (JP)

(73) Assignee: PANASONIC CORPORATION, Osaka (JP)

(21) Appl. No.: 13/957,169

(22) Filed: Aug. 1, 2013

(30) Foreign Application Priority Data
Aug. 8, 2012 (JP) 2012-175711

(51) Int. Cl. H03K 17/96

(52) U.S. Cl. CPC H03K 17/9622
USPC 200/600

(57) ABSTRACT

A touch panel includes a light-permeable substrate, an insulating layer disposed on a lower surface of the substrate, first light-permeable electrodes having substantially strip shapes disposed on a lower surface of the insulating layer, and second light-permeable electrodes having substantially strip shapes disposed on the lower surface of the insulating layer. Each of the first electrodes includes electrode segments having substantially rectangular shapes and connection segments for connecting the first electrode segments. The touch panel has a small number of parts, is inexpensive, and is reliably operated.

### TECHNICAL FIELD

The present invention relates to a touch panel used for operating various electronic devices.

### BACKGROUND

Electronic devices, such as mobile phones and electronic cameras, have been becoming sophisticated and diversified in recent years. Such devices often contain a light-permeable touch panel disposed in front of display elements, such as liquid crystal displays. A user touches the touch panel with a finger while viewing the display of the display elements disposed behind the touch panel so as to switch functions of the device. Such touch panels are demanded to be inexpensive and reliably operated.

FIG. 7 is an exploded perspective view of conventional touch panel 500 disclosed in Japanese Patent Laid-Open Publication No. 2011-146023. Upper electrodes 222 and upper wirings 3 are formed on an upper surface of upper substrate 1 made of a light-permeable film. Upper electrodes 222 made of light-permeable conductive material, such as indium tin oxide, have substantially a strip shape and are arranged in a front-to-back direction. Each of one ends of upper wirings 3 is connected to respective one of ends of upper electrodes 222 while other ends of upper wirings 3 extend to a right end on a periphery of upper substrate 1. Upper wirings 3 extend in a left-to-right direction perpendicular to upper electrodes 222.

Similarly, lower electrodes 5 and lower wirings 6 are formed on an upper surface of lower substrate 4 made of a light-permeable film. Lower electrodes 5 are made of light-permeable conductive material, such as indium tin oxide, and have substantially s strip shape. Lower electrodes 5 are arranged in the left-to-right direction perpendicular to upper electrodes 222. Each of one ends of lower wirings 6 is connected to respective one of ends of lower electrodes 5 while other ends of lower wirings 6 extend to the right end on the periphery of lower substrate 4. Lower wirings 6 extend in the left-to-right direction parallel to lower electrodes 5.

Cover substrate 7 is made of a light-permeable film. Upper substrate 1 is placed on the upper surface of lower substrate 4, and further, cover substrate 7 is placed on the upper surface of upper substrate 1. The substrates are bonded to each other with adhesive, thereby providing touch panel 500.

Touch panel 500 is disposed in front of a display element, such as a liquid crystal display panel, and is mounted to an electronic device. Upper wirings 3 and lower wirings 6 which extend to the right ends on the peripheries of the substrates are electrically connected to an electronic circuit of the electronic device via a flexible wiring board and a connector.

The electronic circuit applies a voltage sequentially to upper wirings 3 and lower wirings 6. Under the condition, when the user touches the upper surface of cover substrate 7 with a finger while viewing the display of the display element behind touch panel 500, the finger operation changes a capacitance between upper electrodes 222 and lower electrodes 5 placed beneath the touched part. The electronic device detects the change in the capacitance, and switches functions of the electronic device.

While various menu items are displayed on the display elements behind the touch panel, when the user touches a certain portion over a desired item on the upper surface of cover substrate 7 with a finger, an electric charge moves to the finger. The finger changes the capacitance between upper electrodes 222 and lower electrodes 5 placed beneath the touched part. The electronic circuit detects the change in capacitance, and selects the desired menu item.

### SUMMARY

A touch panel includes a light-permeable substrate, an insulating layer being ultraviolet curable or electron-ray curable disposed on a lower surface of the substrate, first light-permeable electrodes having substantially strip shapes disposed on a lower surface of the insulating layer, and second light-permeable electrodes having substantially strip shapes disposed on the lower surface of the insulating layer. Each of the first electrodes includes electrode segments having substantially rectangular shapes and connection segments for connecting the first electrode segments.

The touch panel has a small number of parts, is inexpensive, and is reliably operated.

### BRIEF DESCRIPTION OF THE DRAWINGS

FIG. 1 is a plan view of a touch panel in accordance with an exemplary embodiment of the present invention.

FIG. 2 is a cross-section view of the touch panel on line 2-2 shown in FIG. 1.

FIGS. 3A to 3E are partial plan views of the touch panel in accordance with the embodiment for illustrating a method of manufacturing the touch panel.

FIGS. 4A to 4E are partial cross-section views of the touch panel in accordance with the embodiment for illustrating the method of manufacturing the touch panel.

FIGS. 5A to 5C are partial cross-section views of the touch panel in accordance with the embodiment for illustrating the method of manufacturing the touch panel.

FIG. 6A is a partial cross-section view of another touch panel in accordance with the embodiment.

FIG. 6B is a partial cross-section view of still another touch panel in accordance with the embodiment.

FIG. 7 is an exploded perspective view of a conventional touch panel.

### DETAILED DESCRIPTION OF PREFERRED EMBODIMENT

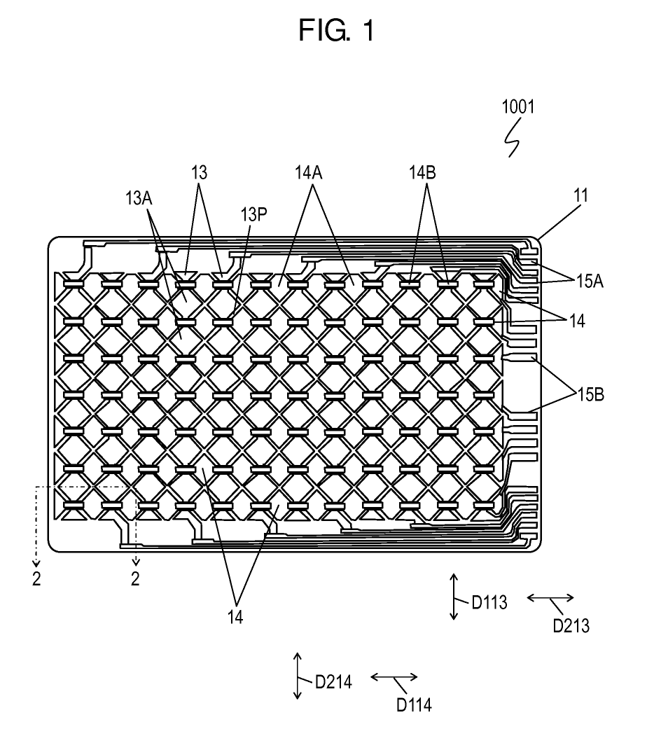

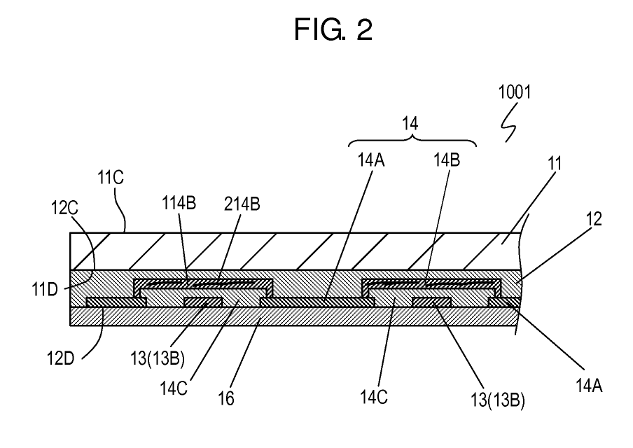

FIG. 1 is a plan view of touch panel 1001 in accordance with an exemplary embodiment of the present invention. FIG. 2 is a cross-section view of touch panel 1001 on line 2-2 shown in FIG. 1. Touch panel 1001 includes substrate 11, insulating layer 12 disposed on lower surface 11D of substrate 11, and electrodes 13 and 14 disposed on lower surface 12D of insulating layer 12.

Substrate 11 is made of a light-permeable film made of polyethylene terephthalate, polyether sulfone, or polycarbonate. Insulating layer 12 is made of light-permeable material, such as ultraviolet-curable or electron-ray curable material, e.g. acrylate or methacrylate, or made of thermosetting epoxies.

Electrodes 13 are made of light-permeable conductive material, such as indium tin oxide or tin oxide, and have substantially strip shapes extending in lengthwise direction D113. Electrodes 13 are formed on lower surface 12D of insulating layer 12 so as to be embedded in insulating layer 12. Electrodes 13 are arranged in arranging direction D213 different from direction D113. According to the embodiment, lengthwise direction D113 is perpendicular to arranging direction D213. Each of electrodes 13 includes electrode segments 13A having substantially rectangular-shapes, and connection segments 13B connecting electrode segments 13A. Clearances 13P having substantially square shapes are provided between electrode segments 13A.

Electrodes 14 are made of light-permeable conductive material and have substantially strip shapes extending in lengthwise direction D114. Each of electrodes 14 includes electrode segments 14A substantially rectangular-shape arranged in direction D114 and connection segments 14B for connecting electrode segments 14A. Electrode segments 14A have substantially rectangular shapes arranged in lengthwise direction D114. Electrodes 14 are arranged in a left-to-right direction, arranging direction D214 different from lengthwise direction D114. According to the embodiment, lengthwise direction D114 is perpendicular to arranging direction D214 and the direction in which electrodes 13 extend. Direction D113 in which electrodes 13 extend is different from direction D114 in which electrodes 14 extend. According to the embodiment, lengthwise direction D113 is perpendicular to lengthwise direction D114. Arranging direction D213 in which electrodes 13 are arranged is different from arranging direction D214 in which electrodes 14 are arranged. According to the embodiment, arranging direction D213 is perpendicular to arranging direction D214. Electrode segments 14A of electrodes 14 are made of light-permeable conductive material, such as indium tin oxide or tin oxide, and are placed in clearances 13P. Connection segments 14B of electrodes 14 contain light-permeable resin 114B, such as acrylate and methacrylate as ultraviolet curable or electron-ray curable resin, and conductive filaments 214B dispersed in light-permeable resin 114B. Conductive filaments 214B are made of conductive material, such as silver, copper, or carbon. Electrodes 14 are formed on lower surface 12D of insulating layer 12 so as to be embedded in insulating layer 12. Electrodes 14 and electrodes 13 are arranged at predetermined intervals.

Light-permeable insulating sections 14C made of, for example, acrylate and methacrylate are formed between connection segments 14B and electrodes 13 by printing or exposing/developing with ultraviolet ray or electron ray. Insulating sections 14C insulate electrodes 13 electrically from electrodes 14.

Wirings 15A and 15B are made of conductive material, such as printed silver or carbon, or deposited copper foil. Each of one ends of wirings 15A and wirings 15B is connected to respective one of ends of electrodes 13 and electrodes 14. Each of another ends of wirings 15A and 15B extended to a right end on a periphery of substrate 11.

Cover layer 16 is made of insulating material, such as acryl, polycarbonate, or epoxy, and formed on lower surface 12D of insulating layer 12 by printing. Cover layer 16 covers lower surface 11D except the right end on the periphery of substrate 11, thereby providing touch panel 1001.

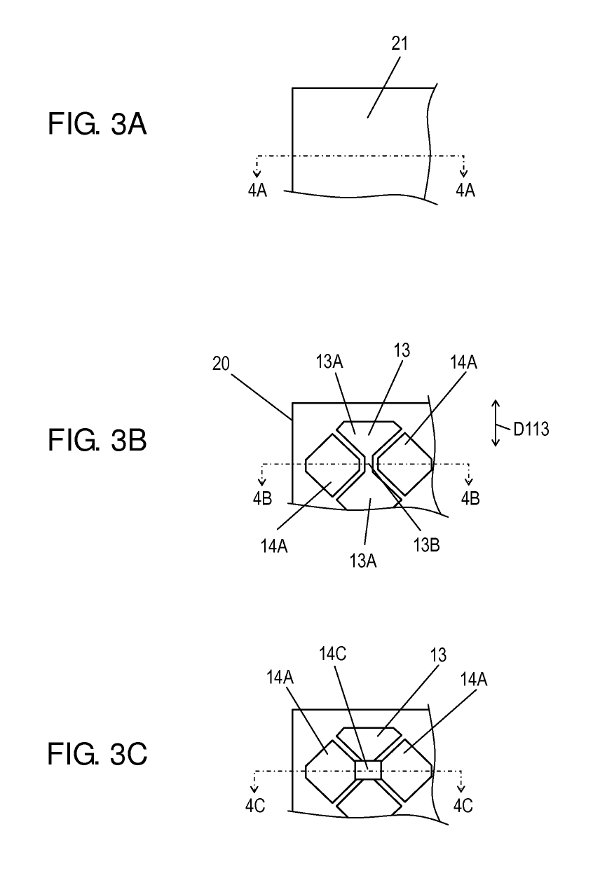

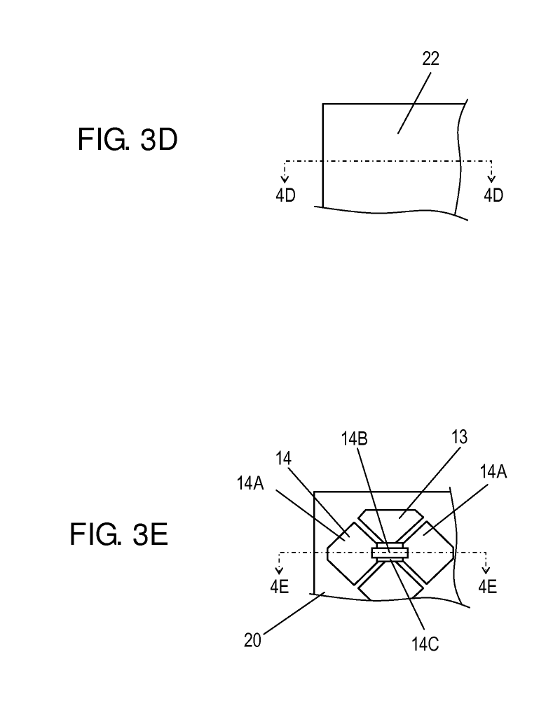

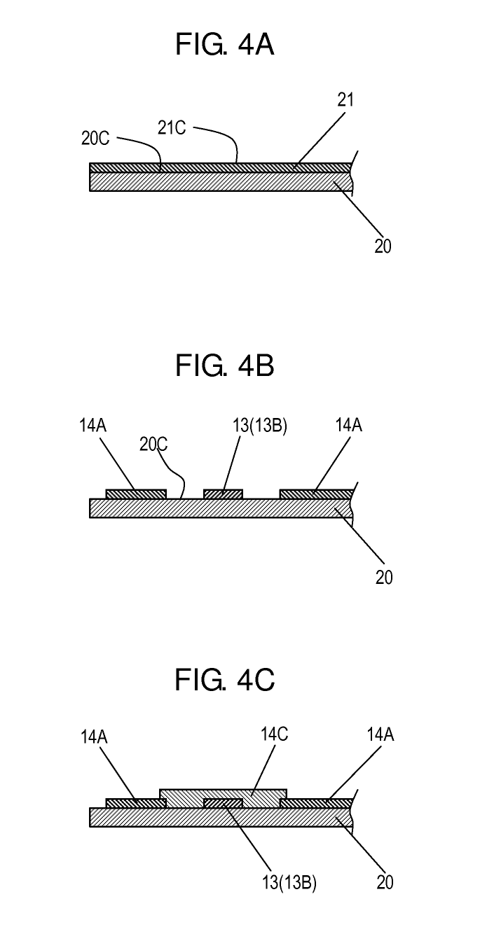

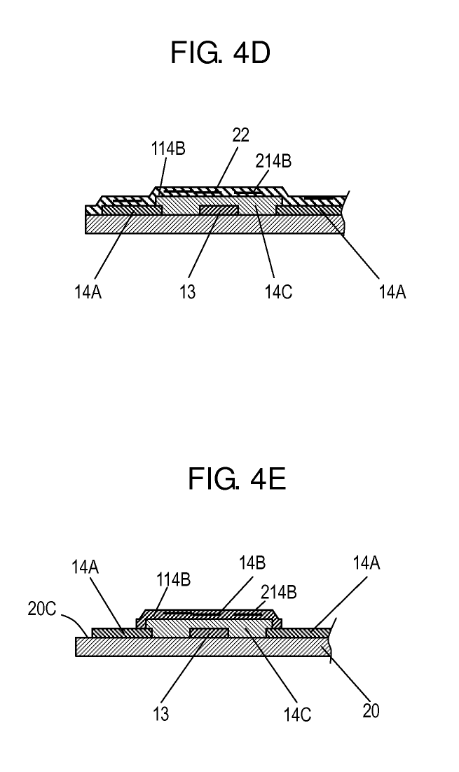

A method of manufacturing touch panel 1001 will be described below. FIGS. 3A to 3E are partial plan views of touch panel 1001 for illustrating the method of manufacturing the touch panel. FIGS. 4A to 4E are partial cross-section views of touch panel 1001 for illustrating the method of manufacturing the touch panel. Specifically, FIG. 4A is a cross-section view of the touch panel on line 4A-4A shown in FIG. 3A. FIG. 4B is a cross-section view of the touch panel on line 4B-4B shown in FIG. 3B. FIG. 4C is a cross-section view of the touch panel on line 4C-4C shown in FIG. 3C. FIG. 4D is a cross-section view of the touch panel on line 4D-4D shown in FIG. 3D. FIG. 4E is a cross-section view of the touch panel on line 4E-4E shown in FIG. 3E.

First, as shown in FIGS. 3A and 4A, conductive thin film 21 made of conductive material, such as indium tin oxide, is formed entirely on upper surface 20C of base 20 having upper surface 20C be removable. Patterns of electrodes 13 and electrode segments 14A are formed on upper surface 21C of conductive thin film 21, and then, are masked with an insulating resin coat, such as a dry film. After that, conductive thin film 21 is dipped into etchant to remove an unnecessary portion thereof. This the procedures forms electrodes 13 and electrode segments 14A on upper surface 20C of base 20, as shown in FIGS. 3B and 4B.

After that, as shown in FIGS. 3C and 4C, insulating sections 14C are formed, by printing or exposing/developing, between electrode segments 14A to cover electrodes 13.

Next, as shown in FIGS. 3D and 4D, curable resin 22 having conductive filaments 214B dispersed therein is bonded to the upper surfaces of electrode segments 14A and insulating sections 14C. Then, curable resin 22 is masked except the part where connection segments 14B are to be formed. After that, curable resin 22 is irradiated with ultraviolet light or electron ray so as to cure portions of curable resin 22 and insulating sections 14C which are not masked.

After that, the coat is removed and a portion of curable resin 22 which is not cured is removed by washing. This procedures forms, as shown in FIGS. 3E and 4E, electrodes 14 having electrode segments 14A and connection segments 14B for connecting electrode segments 14A on upper surface 20C of base 20.

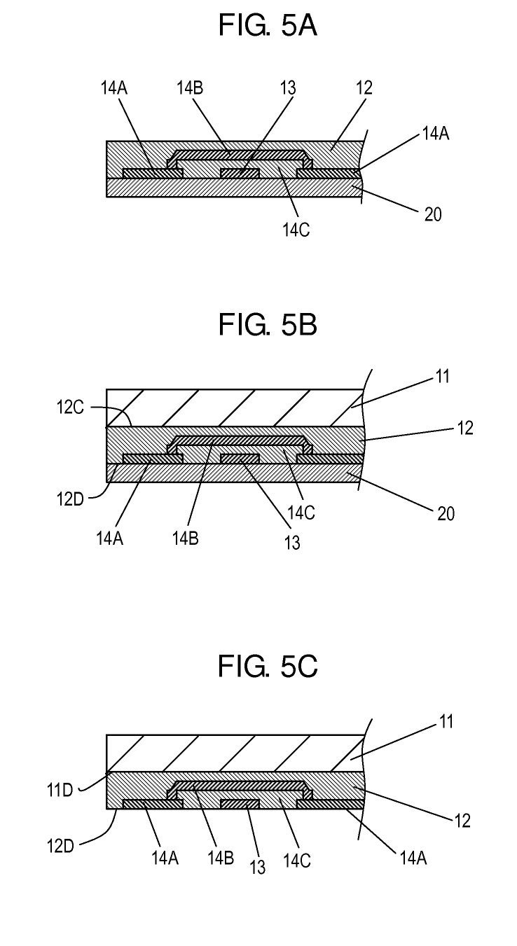

FIGS. 5A to 5C are partial cross-section views of touch panel 1001 for illustrating the method of manufacturing the touch panel. As shown in FIG. 5A, insulating layer 12 made of ultraviolet-curable, electron-ray curable, or thermo-setting material is coated or printed entirely on upper surface 20C of base 20 so as to cover electrodes 13 and 14. After that, substrate 11 is bonded to upper surface 12C of insulating layer 12, as shown in FIG. 5B.

Next, insulating layer 12 is cured. In the case that insulating layer 12 is made of ultraviolet curable or electron-ray curable resin, such as acrylate, the insulating layer is cured by irradiating ultraviolet ray or electron ray. In the case that insulating layer 12 is made of thermosetting resin, such as epoxy, the insulating layer is cured by heating. After insulating layer 12 is cured, as shown in FIG. 5C, base 20 is removed from lower surface 12D of insulating layer 12, thereby providing substrate 11 with insulating layer 12 and electrodes 13 and 14 printed on lower surface 11D.

Finally, cover layer 16 is formed on lower surface 12D of insulating layer 12 having electrodes 13 and 14 embedded to cover the entire surface except the peripheral ends of substrate 11, thereby providing touch panel 1001 shown in FIGS. 1 and 2.

As shown in FIGS. 1 and 3B, each of electrodes 13 includes electrode segments 13A arranged in lengthwise direction D113 and connection segments 13B for connecting electrode segments 13A. In touch panel 1001 according to the embodiment, electrode segments 13A and connection segments 13B are made of the same material, and are disposed on lower surface 12D of insulating layer 12.

An operation of touch panel 1001 will be described below. Touch panel 1001 is placed in front of a display element, such as a crystal liquid display, and is mounted into an electronic device. Wirings 15A and 15B are electrically connected to an electronic circuit of the electronic device via a flexible wiring board or a connector.

While the electronic circuit applies a voltage sequentially to wirings 15A and 15B, when a user touches upper surface 11C of substrate 11 with a finger while viewing the display of the display element disposed behind touch panel 1001, the finger operation changes a capacitance between electrodes 13 and 14 placed beneath the touched part. The electronic circuit detects the change in capacitance to detect the touched part, thereby switching functions of the electronic device.

While, for example, various menu items are displayed on the display element disposed behind the touch panel, when the user touches a certain part corresponding to a desired item on upper surface 11C of substrate 11 with a finger, an amount of electric charge moves to the finger, which changes a capacitance between electrodes 13 and 14 placed beneath the touched part. The electronic circuit detects the change in capacitance, and selects the desired menu item.

In touch panel 1001 according to the embodiment, electrodes 13 are disposed under lower surface 11D of substrate 11 at predetermined intervals across electrodes 14 and insulating layer 12. The structure reduces the number of the substrates, i.e., to reduce the number of parts, decreasing the thickness of the touch panel.

In contrast, conventional touch panel 500 shown in FIG. 7 has upper substrate 1 having upper electrodes 222 formed on the upper surface thereof is disposed on lower substrate 4 having lower electrodes 5 formed on the upper surface thereof. The two substrates are bonded to the lower surface of cover substrate 7. The structure increases the entire thickness of touch panel 500, and increases the number of parts, accordingly increasing production cost.

Conventional touch panel 500 shown in FIG. 7 has a layered structure of relatively thick film-like upper and lower substrates. In contrast, in the structure according to the embodiment, electrodes 13 and 14 are formed on lower surface 11D of substrate 11 via relatively-thin insulating layer 12. This structure allows touch panel 1001 to have a light permeability larger than that of the conventional structure. The advantage allows the display by the display element to be easily read, offering the user easy and reliable operation.

The structure according to the embodiment eliminates the procedure of bonding substrates. Further, electrodes 13 and electrode segments 14A are etched on upper surface 20C of substrate 20 at once. Therefore, touch panel 1001 can be easily assembled and produced inexpensively.

As described above, in touch panel 1001 according to the embodiment, insulating layer 12 includes insulating sections 14C each provided between respective one of electrodes 13 and respective one of electrodes 14. Electrode segments 14A are provided on lower surface 12D of insulating layer 12. Connection segments 14B are positioned above electrodes 13 to face electrodes 13 across insulating sections 14C.

Connection segments 14B are embedded in insulating layer 12 so as not to expose to the outside of insulating layer 12.

Electrode segments 13A of electrodes 13 having substantially rectangular shapes are disposed on lower surface 12D of insulating layer 12 and arranged in lengthwise direction D113. Connection segments 13B are disposed on lower surface 12D of insulating layer 12 to connect electrode segments 13A. Connection segments 14B are positioned above connection segments 13B such that each of connection segments 14B faces respective one of connection segments 13B across respective one of insulating sections 14C of insulating layer 12.

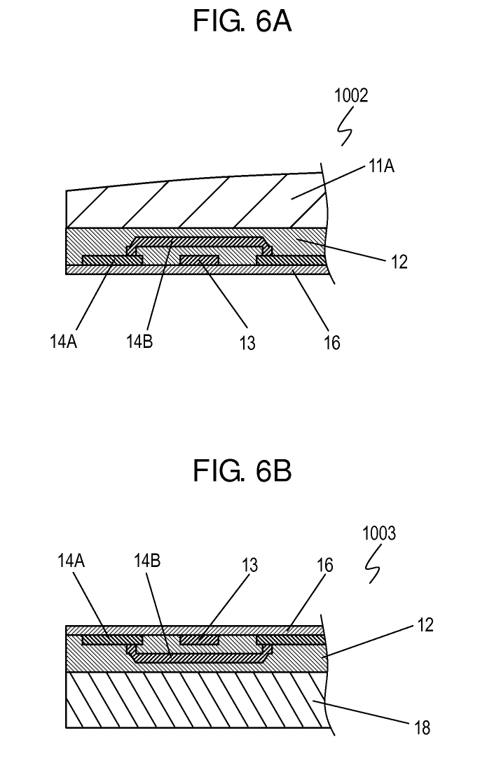

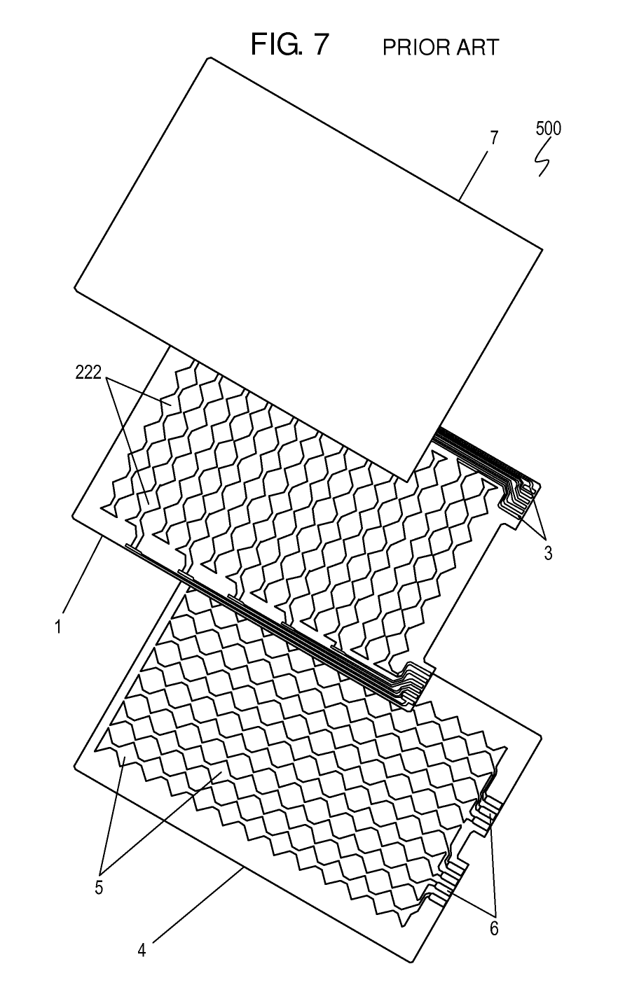

FIG. 6A is a partial cross-section view of another touch panel 1002 according to the embodiment. In FIG. 6A, components identical to those of touch panel 1001 shown in FIG. 1 are denoted by the same reference numerals. Touch panel 1002 includes substrate 11A instead of substrate 11 of touch panel 1001 shown in FIG. 1. In the manufacturing procedures of touch panel 1001 shown in FIG. 1, electrodes 13 and 14 are formed on upper surface 20C of substrate 20, and after that, insulating layer 12 made of ultraviolet-curable or thermosetting material is formed on upper surface 20C of substrate 20. That is, in touch panel 1001, electrodes 13 and 14 and insulating layer 12 are transferred onto lower surface 11D of substrate 11. In touch panel 1002 shown in FIG. 6A, electrodes 13 and 14 and insulating layer 12 are bonded to a lower surface of substrate 11A. Substrate 11A is made of translucent material, such as acryl, polycarbonate, or glass. Substrate 11A has a lens shape having a convex upper surface having a center protruding upward.

FIG. 6B is a partial cross-section view of still another touch panel 1003 according to the embodiment. In FIG. 6B, components identical to those of touch panel 1001 shown in FIG. 1 are denoted by the same reference numerals. Touch panel 1002 shown in FIG. 6A includes display element 18, such as a liquid crystal display, on which substrate 11 is disposed in touch panel 1001 shown in FIG. 1. That is, electrodes 13 and 14 are disposed above display elements 18 via insulating layer 12.

In the touch panels according to the embodiment, electrode segments 14A having substantially rectangular shapes are connected with connection segments 14B. Connection segments 14B are made of light-permeable resin 114B, such as ultraviolet-curable or electron-ray curable resin, having conductive filaments 214B dispersed therein. Electrodes 14 extend in a direction perpendicular to electrodes 13. Thus, electrodes 14 can be easily formed inexpensively, and establish reliable connections between electrode segments 14A. In the case that connection segments 14B are made of film of indium tin oxide by sputtering, a vacuum device is required. Unlike such formed connection segments above, connection segments 14B according to the embodiment can be easily formed by bonding and curing curable resin 22. Further, conductive filaments 214B dispersed in connection segments 14B reliably connect between electrode segments 14A.

In the structure according to the embodiment, each of electrodes 14 includes electrode segments 14A and connection segments 14B for connecting electrode segments 14A, but it is not limited to. Each of electrodes 13 may include electrode segments and connection segments connecting the electrode segments while electrode segments 14A of electrodes 14 are connected in lengthwise direction D114.

Electrodes 13 and 14 according to the embodiment are made of indium tin oxide or tin oxide, but may contain light-permeable resin, such as acryl, and metal filaments, such as silver, dispersed in the resin. Alternatively, electrodes 13 and 14 may be made of light-permeable conductive resin, such as polythiophene and polyaniline.

Touch panels 1001 to 1003 decreases the number of parts, a thickness, and a production cost, and can be reliably operated, and is for operating electronic devices.

In the description according to the embodiment, terms, such as “upper surface”, “lower surface”, and “above” indicate relative directions depending only on relative positional relationship of components, such as a substrate, electrodes, and an insulating layer of the touch panel, and do not indicate absolute directions, such as a vertical direction.

What is claimed is:

1. A touch panel comprising:
a substrate that is light-permeable;
an insulating layer disposed on a lower surface of the substrate, the insulating layer being ultraviolet curable or electron-ray curable;
a plurality of first electrodes that are light-permeable and have substantially a strip shapes extending in a first lengthwise direction, the plurality of first electrodes being disposed on a lower surface of the insulating layer and arranged in a predetermined first arranging direction, each of the plurality of first electrodes including
a plurality of first electrode segments having substantially rectangular shapes arranged in the first lengthwise direction, and
a plurality of first connection segments for connecting the plurality of first electrode segments; and
a plurality of second electrodes that are light-permeable and have substantially strip shapes extending in a second lengthwise direction different from the first lengthwise direction, the second electrodes being disposed on the lower surface of the insulating layer to be spaced apart by a predetermined gap from the plurality of first electrodes, the second electrodes being arranged in a second arranging direction different from the first arranging direction.

2. The touch panel according to claim 1,
wherein the insulating layer has a plurality of insulating sections disposed between each of the plurality of first electrodes and respective one of the plurality of second electrodes,
wherein the plurality of first electrode segments are disposed on the lower surface of the insulating layer, and
wherein the plurality of first connection segments are positioned above the plurality of second electrodes such that each of the plurality of first electrode segments faces respective one of the second electrodes via respective one of the plurality of insulating sections.

3. The touch panel according to claim 2, wherein the plurality of first connection segments are embedded in the insulating layer so as not to be exposed to an outside the insulating layer.

4. The touch panel according to claim 2,
wherein each of the plurality of second electrodes includes:
a plurality of second electrode segments having substantially rectangular shapes disposed on the lower surface of the insulating layer and arranged in the second lengthwise direction; and
a plurality of second connection segments disposed on the lower surface of the insulating layer so as to connect the plurality of the second electrode segments, and
wherein the plurality of first connection segments are positioned above the plurality of second connection segments such that each of the plurality of first connection segment faces respective one of the plurality of second connection segments via respective one of the plurality of insulating sections of the insulating layer.
